(19) United States
(12) Patent Application Publication
(10) Pub. No.: US 2023/0253292 A1
(43) Pub. Date: Aug. 10, 2023

(54) COOLER AND SEMICONDUCTOR DEVICE

(71) Applicant: FUJI ELECTRIC CO., LTD., Kawasaki-shi (JP)

(72) Inventors: Yasutaka SANUKI, Sagamihara-city (JP); Jun NAKAMURA, Machida-city (JP); Yuuji FUJIMOTO, Yokosuka-city (JP)

(73) Assignee: FUJI ELECTRIC CO., LTD., Kawasaki-shi (JP)

(21) Appl. No.: 18/070,069

(22) Filed: Nov. 28, 2022

(30) Foreign Application Priority Data
Jan. 19, 2022 (JP) 2022-006384

(51) Int. Cl. H01L 23/473

(52) U.S. Cl. CPC H01L 23/473

(57) ABSTRACT

A cooler has a cooling main body portion that includes: a cooling wall in the Y direction including a first face with a heat generator thereon, and a second face opposite thereto; first and second flow path extending in the Y direction, the first flow path allowing refrigerant to flow in, and the second flow path allowing the refrigerant to flow out; cooling flow paths with a part of a wall surface comprising the second face; a partition spaced from the cooling wall in the Z direction, separating the first and the second flow paths from the cooling flow paths; and a first narrowing portion at a communication portion between a cooling flow path and the first flow path. The cooling flow paths are positioned between the first and flow paths and the cooling wall, and cause the first and the second flow path to communicate in the X direction.

### CROSS REFERENCE TO RELATED APPLICATIONS

This application is based on, and claims priority from, Japanese Patent Application No. 2022-006384, filed Jan. 19, 2022, the entire content of which is incorporated herein by reference.

### BACKGROUND OF THE INVENTION

### Field of the Invention

The present invention relates to a cooler and to a semiconductor device.

### Description of Related Art

A method of cooling a semiconductor device that includes a heat generating device, such as a switching element, using a refrigerant, such as cooling water, is known. For example, Japanese Patent Application Laid-Open Publication No. 2020-073845 discloses a configuration in which a heat transfer plate thermally coupled to a heat generating device is cooled using a cooling fluid to cool the heat generating device. Furthermore, for example, Japanese Patent Application Laid-Open Publication No. 2021-027097 discloses an apparatus including an external cooling mechanism that externally cools a semiconductor package including semiconductor chips as heat generating sources, as an apparatus that measures transient heat of the semiconductor package. The external cooling mechanism cools, for example, a heat spreader that forms a lower face of the semiconductor package using liquid refrigerant. Efficient cooling of a semiconductor device is demanded for a cooler that cools a semiconductor device.

### SUMMARY OF THE INVENTION

In view of the above circumstance, one aspect of the present invention is directed to providing a cooler that efficiently cools a semiconductor device.

A cooler according to a preferred aspect of the present invention includes a cooling main body portion extending in a first direction, where the cooling main body portion includes: a cooling wall including a first face on which a heat generator is arranged, and a second face opposite to the first face; a first flow path extending in the first direction and allowing refrigerant to flow in from one end thereof; a second flow path extending in the first direction and allowing the refrigerant to flow out from one end thereof; a plurality of cooling flow paths each having a wall surface, a part of which is constituted of the second face; a partition arranged to be spaced from the cooling wall in a third direction perpendicular to the first face, separating the first flow path from the cooling flow paths, and separating the second flow path from the cooling flow paths; and a first narrowing portion provided at a communication portion between a first cooling flow path among the cooling flow paths and the first flow path, the cooling flow paths are arrayed in the first direction and extend in a second direction intersecting with the first direction, and are positioned between the first and second flow paths and the cooling wall in the third direction, and each of the cooling flow paths causes the first flow path and the second flow path to communicate with each other in the second direction.

A cooler according to another preferred aspect of the present invention includes a cooling main body portion extending in a first direction. The cooling main body portion includes: a cooling wall including a first face on which a heat generator is arranged, and a second face opposite to the first face; a first flow path extending in the first direction and allowing refrigerant to flow in from one end thereof; a second flow path extending in the first direction and allowing the refrigerant to flow out from one end thereof; a plurality of cooling flow paths each having a wall surface, a part of which is constituted of the second face; a partition arranged to be spaced from the cooling wall in a third direction perpendicular to the first face, separating the first flow path from the cooling flow paths, and separating the second flow path from the cooling flow paths; and a second narrowing portion provided in a first cooling flow path among the cooling flow paths, the cooling flow paths are arrayed in the first direction and extend in a second direction intersecting with the first direction, and are positioned between the first and second flow paths and the cooling wall in the third direction, and each of the cooling flow paths causes the first flow path and the second flow path to communicate with each other in the second direction.

A semiconductor device according to a preferred aspect of the present invention includes the cooler described above.

### BRIEF DESCRIPTION OF THE DRAWINGS

FIG. 1 is an exploded perspective view schematically illustrating relevant parts of a power converter according to a first embodiment;

FIG. 2 is an explanatory diagram for explaining a head portion illustrated in FIG. 1;

FIG. 3 is an explanatory diagram for explaining a main body portion illustrated in FIG. 1;

FIG. 4 is a plan view illustrating an example of arrangement of nozzles illustrated in FIG. 3;

FIG. 5 is another explanatory diagram for explaining the main body portion illustrated in FIG. 1;

FIG. 6 is an explanatory diagram for explaining an example of a power converter according to a comparative example;

FIG. 7 is a perspective view illustrating an example of a schematic internal structure of the power converter in its entirety;

FIG. 8 is an explanatory diagram for explaining an example of a power converter according to a second embodiment;

FIG. 9 is an explanatory diagram for explaining an example of a power converter according to a third embodiment;

FIG. 10 is an explanatory diagram for explaining effects of a cooler illustrated in FIG. 9;

FIG. 11 is an explanatory diagram for explaining an example of a power converter according to a fourth embodiment;

FIG. 12 is an explanatory diagram for explaining an example of a power converter according to a first modification; and

FIG. 13 is an explanatory diagram for explaining an example of a power converter according to a second modification.

### DESCRIPTION OF EMBODIMENTS

Embodiments according to the present invention are explained below with reference to the drawings. It is to be noted that the dimensions and scales of parts in the drawings are different from actual products as appropriate. The embodiments described below are preferable specific examples of the present invention. Therefore, the following embodiments include various technically preferable limitations. However, the scope of the present invention is not limited to the embodiments unless it is described in the following explanations that the present invention is specifically limited.

### A. Embodiments

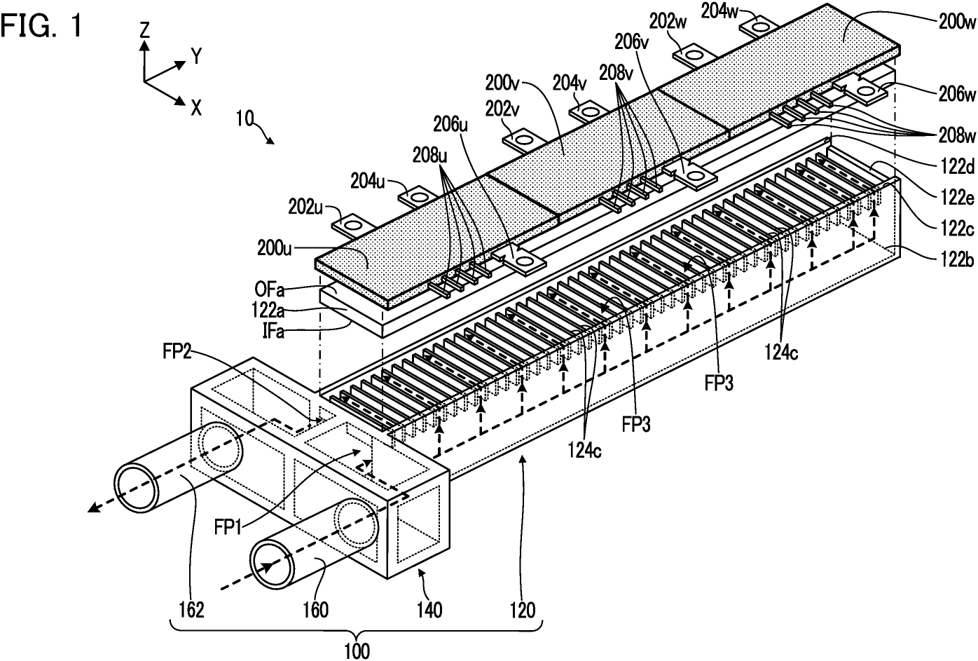

Embodiments of the present invention are explained below. An example of the outline of a power converter 10 according to a first embodiment is explained first with reference to FIG. 1.

### A1. First Embodiment

FIG. 1 is an exploded perspective view schematically illustrating relevant parts of the power converter 10 according to the first embodiment.

A rectangular coordinate system with three axes including an X-axis, a Y-axis, and a Z-axis perpendicular to each other is hereinafter adopted for the purpose of illustration. Hereinafter, the direction indicated by the arrow of the X-axis is referred to as the “+X direction” and the direction opposite to the +X direction is referred to as the “-X direction.” The direction indicated by the arrow of the Y-axis is referred to as the “+Y direction” and the direction opposite to the +Y direction is referred to as the”-Y direction.” The direction indicated by the arrow of the Z-axis is referred to as the “+Z direction” and the direction opposite to the +Z direction is referred to as the “-Z direction.” Hereinafter, the +Y direction and the -Y direction are sometimes referred to as the “Y direction” without distinguishing, and the +X direction and the -X direction are sometimes referred to as the “X direction” without distinguishing. The +Z direction and the -Z direction are sometimes referred to as the “Z direction” without distinguishing.

Each of the +Y direction and the -Y direction is an example of a “first direction,” each of the +X direction and the -X direction is an example of a “second direction,” and each of the +Z direction and the -Z direction is an example of a “third direction.” Hereinafter, viewing an object from a certain direction is sometimes referred to as a “plan view.”

Any power semiconductor device such as an inverter or a converter can be adopted as the power converter 10. The power converter 10 is an example of a “semiconductor device.” In the present embodiment, a power semiconductor device that converts DC power input to the power converter 10 to AC power of three phases including a U phase, a V phase, and a W phase is assumed as the power converter 10.

For example, the power converter 10 has three semiconductor modules 200u, 200v, and 200w that convert DC power to AC power, and a cooler 100 that cools the semiconductor modules 200u, 200v, and 200w. The semiconductor modules 200u, 200v, and 200w are examples of a “heat generator.”

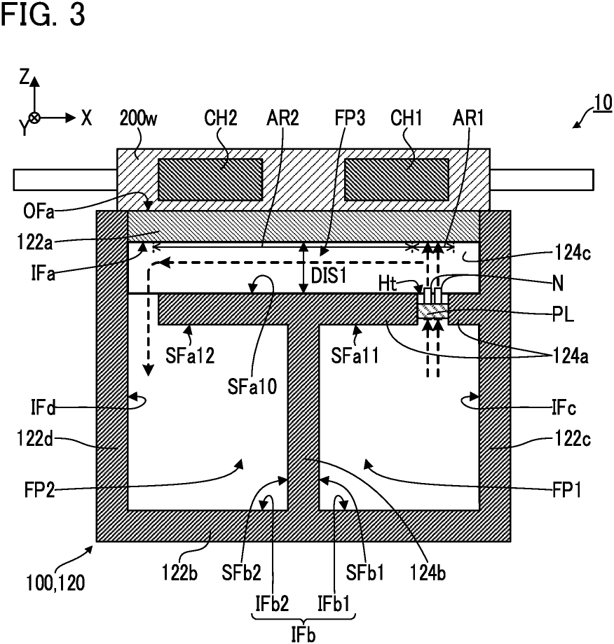

Each of the semiconductor modules 200u, 200v, and 200w is, for example, a power semiconductor module that has power semiconductor chips (for example, semiconductor chips CH1 and CH2 illustrated in FIG. 3) including a power semiconductor element such as a switching element accommodated in a resin case. For example, a power MOSFET (Metal Oxide Semiconductor Field Effect Transistor) or an IGBT (Insulated Gate Bipolar Transistor) corresponds to the switching element.

The semiconductor module 200u has, for example, input terminals 202u and 204u, an output terminal 206u, and a plurality of control terminals 208u. For example, the semiconductor module 200u converts DC power input to the input terminals 202u and 204u into U-phase AC power of the three-phase AC power, and outputs the U-phase AC power from the output terminal 206u. The potential of the input terminal 202u is, for example, higher than that of the input terminal 204u. Furthermore, control signals for controlling an operation of a switching element and the like included in the semiconductor module 200u are input to the control terminals 208u, respectively.

Each of the semiconductor modules 200v and 200w is the same as the semiconductor module 200u, except for outputting the V-phase or W-phase AC power of the three-phase AC power. For example, the semiconductor module 200v has input terminals 202v and 204v, an output terminal 206v, and a plurality of control terminals 208v, and outputs the V-phase AC power from the output terminal 206v. For example, the semiconductor module 200w has input terminals 202w and 204w, an output terminal 206w, and a plurality of control terminals 208w, and outputs the W-phase AC power from the output terminal 206w.

Hereinafter, the semiconductor modules 200u, 200v, and 200w are sometimes collectively referred to as “semiconductor module 200.” The input terminals 202u, 202v, and 202w are sometimes collectively referred to as “input terminal 202,” the input terminals 204u, 204v, and 204w are sometimes collectively referred to as “input terminal 204,” and the output terminals 206u, 206v, and 206w are sometimes collectively referred to as “output terminal 206.”

The cooler 100 has a main body portion 120 extending in the Y direction, a supply pipe 160 that supplies a refrigerant to the main body portion 120, a discharge pipe 162 that discharges the refrigerant from the main body portion 120, and a head portion 140 that connects the supply pipe 160 and the discharge pipe 162 to the main body portion 120. The dashed arrows in FIG. 1 indicate an example of the flow of refrigerant. A case in which the refrigerant is a fluid such as water is assumed in the present embodiment.

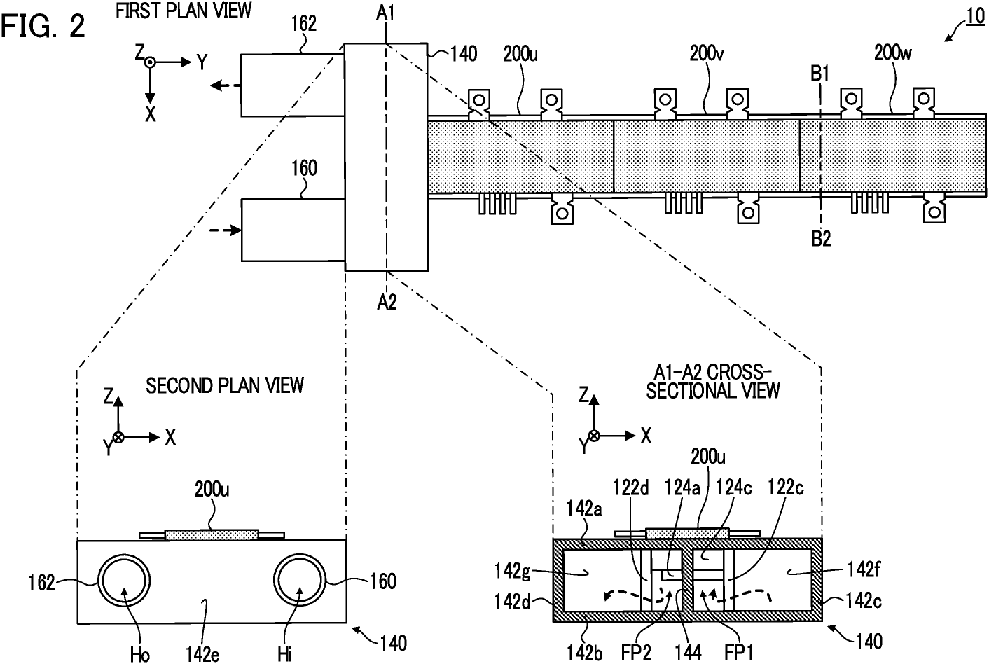

The main body portion 120 is an example of a “cooling main body portion.” FIG. 1 illustrates the outline of the main body portion 120. Details of the main body portion 120 are explained with reference to FIGS. 3, 4, and 5 described later. The head portion 140 is explained with reference to FIG. 2, described later.

The main body portion 120 is, for example, a hollow structure formed into a cuboid extending in the Y direction. For example, the main body portion 120 has an inflow path FP1 extending in the Y direction and allowing the refrigerant to flow in from one end, an outflow path FP2 extending in the Y direction and allowing the refrigerant to flow out from one end, and a plurality of cooling flow paths FP3. The other end (an end portion in the +Y direction) of each of the inflow path FP1 and the outflow path FP2 is defined by an outer wall 122e. The inflow path FP1 is an example of a “first flow path” and the outflow path FP2 is an example of a “second flow path.”

The main body portion 120 has an outer wall 122a on which the semiconductor modules 200 are arranged. The outer wall 122a includes an outer face OFa on which the semiconductor modules 200 are arranged, and an inner face IFa on the opposite side to the outer face OFa. The inner face IFa is a part of wall surfaces of the cooling flow paths FP3. The outer wall 122a is an example of a “cooling wall,” the outer face OFa is an example of a “first face,” and the inner face IFa is an example of a “second face.”

The cooling flow paths FP3 are arrayed in the Y direction and extend in the X direction intersecting with the Y direction. One end and the other end of each of the cooling flow paths FP3 are defined by outer walls 122c and 122d, respectively. For example, the main body portion 120 has a plurality of partitions 124c arrayed in the Y direction and extending in the X direction. Two of the cooling flow paths FP3 adjacent to each other are separated from each other by a partition 124c positioned between the two cooling flow paths FP3.

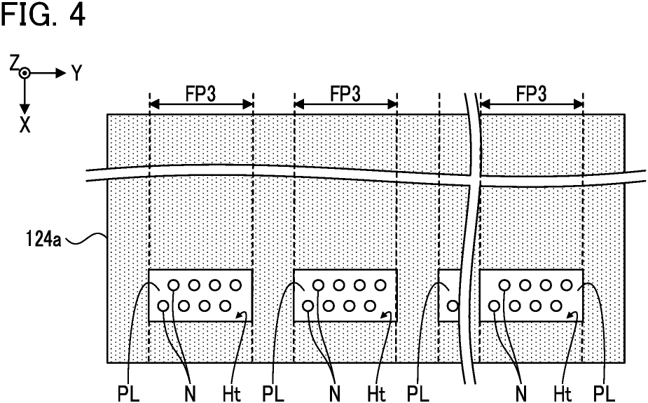

Although FIG. 1 illustrates the partitions 124c away from the outer wall 122a to clarify the flow of the refrigerant, a case in which the partitions 124c are formed integrally with the outer wall 122a as illustrated in FIG. 4 is assumed in the present embodiment. The number of the partitions 124c is not limited to a plurality. For example, when the number of the cooling flow paths FP3 is two, there may be only one partition 124c.

The cooling flow paths FP3 are positioned between the inflow path FP1 and the outflow path FP2, and the outer wall 122a in the Z direction perpendicular to the outer face OFa. Each of the cooling flow paths FP3 causes the inflow path FP1 and the outflow path FP2 to communicate with each other in the X direction.

The cooler 100 cools the semiconductor modules 200 arranged on the outer face OFa of the outer wall 122a using the refrigerant flowing through the cooling flow paths FP3 having the inner face IFa of the outer wall 122a as a part of the wall surfaces. For example, heat generated in the semiconductor modules 200 is released to the refrigerant via the outer wall 122a.

The main body portion 120 is made of a material having high thermal conductivity. Specific constituent materials of the main body portion 120 include metals such as copper, aluminum, and alloys of either thereof. The head portion 140, the supply pipe 160, and the discharge pipe 162 are made of, for example, the same material as the main body portion 120. That is, specific constituent materials of the head portion 140, the supply pipe 160, and the discharge pipe 162 include metals such as copper, aluminum, and alloys of either thereof. Some or all of the head portion 140, the supply pipe 160, and the discharge pipe 162 may be made of a material different from the main body portion 120.

The shape of the main body portion 120 is not limited to a cuboid extending in the Y direction. For example, the shape of the main body portion 120 in plan view from the -Y direction may be a shape having curved lines. That is, the outer walls 122c and 122d may be curved.

The head portion 140 is explained next with reference to FIG. 2.

FIG. 2 is an explanatory diagram for explaining the head portion 140 illustrated in FIG. 1. A first plan view of FIG. 2 is a plan view of the cooler 100 and the semiconductor modules 200 planarly viewed from the +Z direction, and a second plan view is a plan view of the cooler 100 and the semiconductor modules 200 planarly viewed from the -Y direction. An A1-A2 cross-sectional view of FIG. 2 is a cross-sectional view of the cooler 100 along a line A1-A2 in the first plan view. In FIG. 2, illustrations of reference signs such as the input terminal 202u are omitted for simplicity. Illustrations of reference signs such as the input terminal 202u are appropriately omitted also in the drawings after FIG. 2.

The head portion 140 is, for example, a hollow cuboid having an opening communicating with the inflow path FP1, an opening communicating with the outflow path FP2, a supply port Hi, and a discharge port Ho.

The supply port Hi and the discharge port Ho are holes penetrating through an outer wall 142e substantially parallel to an X-Z plane as illustrated in the second plan view. Descriptions such as “substantially parallel” indicate concepts including an error. For example, in a case in which parts are “substantially parallel,” it suffices that the parts be parallel to each other in design. The supply pipe 160 and the discharge pipe 162 are connected to the outer wall 142e. For example, the supply pipe 160 is connected to the outer wall 142e in such a manner that the flow path in the supply pipe 160 communicates with the supply port Hi, and the discharge pipe 162 is connected to the outer wall 142e in such a manner that the flow path in the discharge pipe 162 communicates with the discharge port Ho.

As illustrated in the A1-A2 cross-sectional view, the head portion 140 has outer walls 142a and 142b substantially parallel to an X-Y plane, outer walls 142c and 142d substantially parallel to a Y-Z plane, and outer walls 142f and 142g substantially parallel to the X-Z plane, as well as the outer wall 142e. The head portion 140 also has a partition 144 substantially parallel to the Y-Z plane.

The outer walls 142f and 142g are arranged, for example, away from the outer wall 142e in the +Y direction and are connected to the outer walls 122c and 122d of the main body portion 120, respectively. The partition 144 separating a flow path from the supply port Hi to the inflow path FP1 and a flow path from the outflow path FP2 to the discharge port Ho from each other is arranged between the outer walls 122c and 122d of the main body portion 120 in the X direction. For example, the partition 144 is connected to the outer walls 142a and 142b, a partition 124c closest to the head portion 140 among the partitions 124c of the main body portion 120, a partition 124a of the main body portion 120, and a partition 124b of the main body portion 120, which will be described later with reference to FIG. 3.

The shape of the head portion 140 is not limited to that illustrated in FIG. 2. For example, the shape of the head portion 140 in plan view from the -Y direction may be a shape having curved lines. That is, the outer walls 142c and 142d may be curved.

The main body portion 120 is explained next with reference to FIGS. 3, 4, and 5.

FIG. 3 is an explanatory diagram for explaining the main body portion 120 illustrated in FIG. 1. FIG. 3 is a cross-sectional view of the power converter 10 along a line B1-B2 illustrated in the first plan view of FIG. 2. A dashed arrow in FIG. 3 indicates the flow of the refrigerant. Illustrations of parts other than the semiconductor chips CH1 and CH2 included in the semiconductor module 200 are omitted in the cross-sectional view of the semiconductor module 200. Illustrations of parts other than the semiconductor chips CH1 and CH2 included in the semiconductor module 200 are also omitted in cross-sectional views of the semiconductor module 200 illustrated in the drawings following FIG. 3.

Each of the semiconductor modules 200 has the semiconductor chips CH1 and CH2 being heat generating sources. The semiconductor chips CH1 and CH2 are, for example, power semiconductor chips each including a power semiconductor element such as a switching element.

The main body portion 120 has partitions 124a and 124b in addition to the outer wall 122a, an outer wall 122b, the outer walls 122c, 122d, and 122e and the partitions 124c explained with reference to FIG. 1. The main body portion 120 further has a plurality of attachment plates PL corresponding to the cooling flow paths FP3 on a one-to-one basis, and a plurality of nozzles N attached to each of the attachment plates PL. The partition 124a is an example of a “partition.”

The partition 124a is arranged between the outer walls 122a and 122b. That is, the partition 124a is arranged to be spaced from the outer wall 122a in the -Z direction. In the present embodiment, a case in which the partition 124a is substantially parallel to the outer wall 122a is assumed. For example, a face SFa10 directed to the inner face IFa of the outer wall 122a among the faces of the partition 124a is substantially parallel to the inner face IFa of the outer wall 122a. It is permissible for the face SFa10 of the partition 124a to not be parallel to the inner face IFa of the outer wall 122a. For example, the face SFa10 of the partition 124a may be inclined in such a manner that an edge of the face SFa10 in the -X direction is closer to the outer wall 122a.

The partition 124a arranged between the outer walls 122a and 122b separates the inflow path FP1 from the cooling flow paths FP3, and separates the outflow path FP2 from the cooling flow paths FP3. In the present embodiment, for example, an edge of the partition 124a in the +X direction is connected to an inner face IFc of the outer wall 122c, and a space enabling the outflow path FP2 to communicate with the cooling flow paths FP3 is provided between an edge of the partition 124a in the -X direction and an inner face IFd of the outer wall 122d.

A plurality of through-holes Ht penetrating through the partition 124a are formed on a portion of the partition 124a between the edge of the partition 124a in the +X direction and the partition 124b, described later. A corresponding attachment plate PL is attached to each of the through holes Ht to close the through hole Ht. The nozzles N extending along the Z direction and causing the refrigerant to flow from the inflow path FP1 to the cooling flow paths FP3 are attached to each of the attachment plates PL. In the present embodiment, the nozzles N overlap the semiconductor chip CH1 being the heat generating source in plan view from the +Z direction. The nozzles N are an example of a “first narrowing portion.” In the present embodiment, a case in which the nozzles N are provided at the communication portion between each of the cooling flow paths FP3 and the inflow path FP1 is assumed. Therefore, each of the cooling flow paths FP3 is an example of a “first cooling flow path.”

The partition 124b is arranged between the outer walls 122c and 122d and is connected to the partition 124a and the outer wall 122b. The partition 124b is, for example, a wall substantially parallel to the Y-Z plane and separates the inflow path FP1 and the outflow path FP2 from each other. For example, a face SFb1 of the partition 124b is a face directed to the inner face IFc of the outer wall 122c among the faces of the partition 124b, and is substantially parallel to the inner face IFc of the outer wall 122c. A face SFb2 of the partition 124b is a face directed to the inner face IFd of the outer wall 122d among the faces of the partition 124b, and is substantially parallel to the inner face IFd of the outer wall 122d.

For example, a face SFall of the partition 124a, the face SFb1 of the partition 124b, and an inner face IFb1 of the outer wall 122b are a part of the wall surface of the inflow path FP1. A face SFa12 of the partition 124a, the face SFb2 of the partition 124b, and an inner face IFb2 of the outer wall 122b are a part of the wall surface of the outflow path FP2. The face SFall of the partition 124a is a portion of the opposite face to the face SFa10, which is located in the +X direction relative to the partition 124b and the face SFa12 of the partition 124a is a portion of the opposite face to the face SFa10, which is located in the -X direction relative to the partition 124b. The inner face IFb1 of the outer wall 122b is a portion of the inner face IFb of the outer wall 122b, which is located in the +X direction relative to the partition 124b and the inner face IFb2 of the outer wall 122b is a portion of the inner face IFb of the outer wall 122b, which is located in the -X direction relative to the partition 124b.

The refrigerant having flowed in the inflow path FP1 passes through the nozzles N to flow in the cooling flow paths FP3. The refrigerant having flowed in the cooling flow paths FP3 passes through the space between the edge of the partition 124a in the -X direction and the inner face IFd of the outer wall 122d to flow in the outflow path FP2. That is, in the present embodiment, each of the cooling flow paths FP3 communicates with the inflow path FP1 at one end and communicates with the outflow path FP2 at the other end.

The partitions 124c are walls substantially perpendicular to the outer wall 122a and extend in the X direction. For example, the partitions 124c are arranged between the partition 124a and the outer wall 122a and are connected to the outer walls 122a, 122c, and 122d and the partition 124a. That is, the partitions 124c are connected to both the partition 124a and the outer wall 122a in the present embodiment. The partitions 124c may be connected to only one of the partition 124a and the outer wall 122a. Each of the cooling flow paths FP3 is formed, for example, between partitions 124c adjacent to each other. The inner face IFa of the outer wall 122a and the face SFa10 of the partition 124a are parts of the wall surfaces of the cooling flow paths FP3.

In the present embodiment, the semiconductor modules 200 are arranged on the outer face OFa of the outer wall 122a including the inner face IFa that is a part of the wall surfaces of the cooling flow paths FP3. Accordingly, for example, heat generated in the semiconductor modules 200 (more specifically, heat generated in the semiconductor chips CH1 and CH2 and the like) is transferred from a face directed to the outer face OFa of the outer wall 122a in the surface of the semiconductor modules 200 to the refrigerant inside the cooling flow paths FP3. The semiconductor modules 200 are cooled by so-called “single side cooling”. Although not particularly illustrated in FIG. 3, a TIM (Thermal Interface Material) such as thermal conductive grease, thermal conductive adhesive, thermal conductive sheet, or solder may be interposed between the semiconductor modules 200 and the outer face OFa of the outer wall 122a.

In the present embodiment, the refrigerant in the inflow path FP1 is sprayed substantially perpendicularly to the outer wall 122a by the nozzles N extending in the Z direction and flows in the cooling flow paths FP3. Accordingly, the refrigerant impinges on an area AR1 including a portion of the inner face IFa of the outer wall 122a overlapping with the nozzles N in plan view from the +Z direction. The refrigerant having impinged on the area AR1 on the inner face IFa moves, for example, in the -X direction, substantially parallel to the inner face IFa.

Heat at a portion of the inner face IFa of the outer wall 122a near the area AR1 that is impinged by the refrigerant is more efficiently transferred to the refrigerant impinging on the area AR1 than that at a portion far from the area AR1 impinged by the refrigerant. In the present embodiment, the area AR1 overlaps with the semiconductor chip CH1 in plan view from the +Z direction. Therefore, in the present embodiment, the semiconductor chip CH1 is efficiently cooled by the refrigerant having impinged on the area AR1 of the outer wall 122a. An area AR2 on the inner face IFa is an area cooled by transfer of heat to the refrigerant moving in the -X direction, and is an area where the cooling effect obtained by the refrigerant impinging on the inner face IFa is smaller than in the area AR1.

The cooling efficiency in the area AR2 on the inner face IFa is improved, for example, by increasing the flow rate of the refrigerant passing between the area AR2 and the face SFa10 of the partition 124a. Therefore, a distance DIS1 between the area AR2 and the face SFa10 of the partition 124a is small in the present embodiment to increase the flow rate of the refrigerant passing between the area AR2 and the face SFa10 as compared to a case in which the distance DIS1 between the area AR2 and the face SFa10 is large. This enables the semiconductor chip CH2 and the like overlapping with the area AR2 in plan view from the +Z direction to be efficiently cooled in the present embodiment.

Furthermore, since the cooling flow paths FP3 are positioned between the inflow path FP1 and the outflow path FP2, and the outer wall 122a in the Z direction in the present embodiment, a space can be provided in the Z direction of the terminals (such as the input terminals 202 and 204 and the output terminals 206) of the semiconductor modules 200. For example, the inflow path FP1 and the outflow path FP2 are positioned in the -Z direction relative to the partitions 124c separating the cooling flow paths FP3. Accordingly, in the present embodiment, the inner face IFc of the outer wall 122c defining one end of each of the cooling flow paths FP3 can be a part of the wall surface of the inflow path FP1, and the inner face IFd of the outer wall 122d defining the other end of each of the cooling flow paths FP3 can be a part of the wall surface of the outflow path FP2. In this case, a space is provided in the Z direction of the terminals of the semiconductor modules 200, and therefore, lines and the like can be easily connected to the terminals of the semiconductor modules 200.

FIG. 4 is a plan view illustrating an example of arrangement of the nozzles N illustrated in FIG. 3. A plan view of the partition 124a to which the attachment plates PL are attached seen from the +Z direction is illustrated in FIG. 4.

The through-holes Ht corresponding to the cooling flow paths FP3 on a one-to-one basis are formed on the partition 124a. As explained with reference to FIG. 3, the attachment plates PL closing the through-holes Ht are attached to the through-holes Ht, respectively. In the example illustrated in FIG. 4, eight nozzles N arrayed in two lines along the Y direction are attached to each of the attachment plates PL.

The number of the nozzles N attached to each of the attachment plates PL and arrangement thereof are not limited to the example illustrated in FIG. 4. For example, nine nozzles N arranged in three rows and three columns may be attached to each of the attachment plates PL, or four nozzles N arranged in two rows and two columns may be attached thereto. Alternatively, only one nozzle N may be attached to each of the attachment plates PL. That is, one or more nozzles N are attached to each of the attachment plates PL.

One through hole Ht (for example, one through hole Ht obtained by connecting the through holes HT illustrated in FIG. 4) extending in the Y direction may be formed on the partition 124a, instead of the through holes Ht.

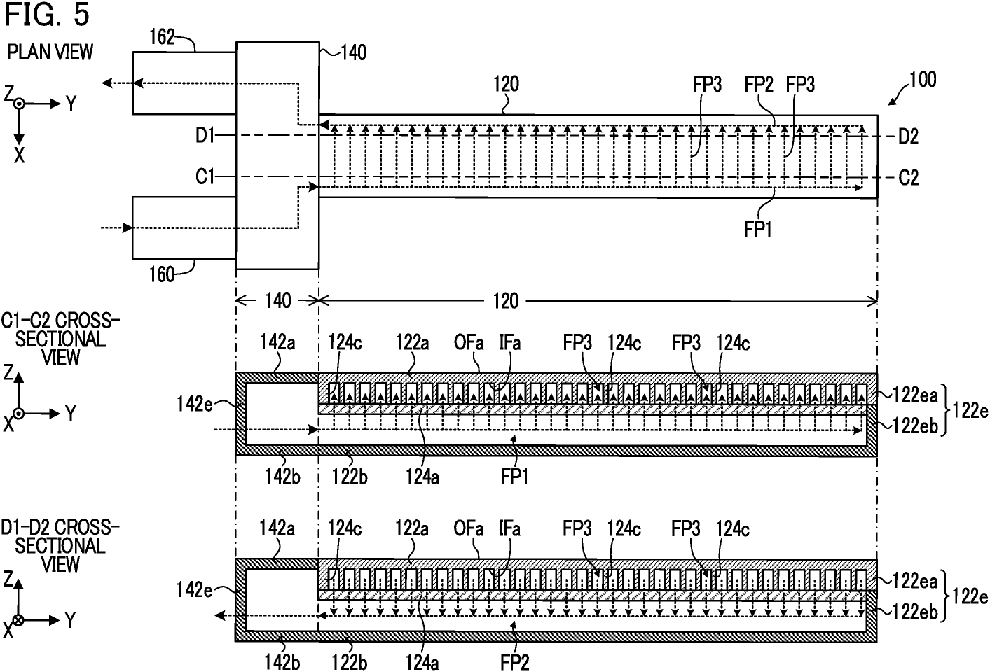

FIG. 5 is another explanatory diagram for explaining the main body portion 120 illustrated in FIG. 1. A plan view of FIG. 5 is a plan view of the cooler 100 planarly viewed from the +Z direction. A C1-C2 cross-sectional view of FIG. 5 is a cross-sectional view of the cooler 100 along a line C1-C2 in the plan view of FIG. 5, and a D1-D2 cross-sectional view of FIG. 5 is a cross-sectional view of the cooler 100 along a line D1-D2 in the plan view of FIG. 5. Dashed arrows in the drawings indicate the flow of the refrigerant. Illustrations of the attachment plates PL and the nozzles N are omitted in the C1-C2 cross-sectional view of FIG. 5.

The refrigerant having flowed from the supply pipe 160 into the inflow path FP1 flows into any of the cooling flow paths FP3 via any of the nozzles N illustrated in FIG. 4. Heat exchange is performed between the refrigerant having flowed into the cooling flow paths FP3 and the semiconductor modules 200. The refrigerant having flowed into the cooling flow paths FP3 flows in the outflow path FP2. The refrigerant having flowed into the outflow path FP2 is discharged from the discharge pipe 162. In this way, in the present embodiment, the semiconductor modules 200 (more specifically, for example, the semiconductor chips CH1 and CH2) can be cooled by fresh refrigerant flowing from the inflow path FP1 into the cooling flow paths FP3. The fresh refrigerant is, for example, refrigerant before the heat exchange with the semiconductor modules 200, or refrigerant at almost the same temperature as that of the refrigerant before the heat exchange with the semiconductor modules 200.

In the present embodiment, the partitions 124c are formed integrally with the outer wall 122a as illustrated in the C1-C2 cross-sectional view and the D1-D2 cross-sectional view. For example, the contact area between a structure in which the outer wall 122a and the partitions 124c are formed integrally with each other and the refrigerant is larger than the contact area between the outer wall 122a and the refrigerant in a case in which the partitions 124c are not connected to the outer wall 122a. Therefore, the efficiency of heat transfer in a case in which heat is transferred from the semiconductor modules 200 to the refrigerant via the outer wall 122a can be improved in the present embodiment.

In FIG. 5, a portion of the outer wall 122e formed integrally with the outer wall 122a is also referred to as “outer wall 122ea” and a portion of the outer wall 122e other than the outer wall 122ea is also referred to as “outer wall 122eb.”

A manufacturing method for parts such as the partitions 124c is not particularly limited. For example, the partitions 124c formed integrally with the outer wall 122a may be connected to the partition 124a or be unconnected to the partition 124a. For example, it is also possible for the partitions 124c to not be formed integrally with the outer wall 122a. In this case, the partitions 124c may be formed integrally with the partition 124a. The partitions 124c formed integrally with the partition 124a may be connected to the outer wall 122a or be unconnected to the outer wall 122a. Alternatively, the partitions 124c formed separately from the outer wall 122a and the partition 124a may be connected to one or both of the outer wall 122a and the partition 124a.

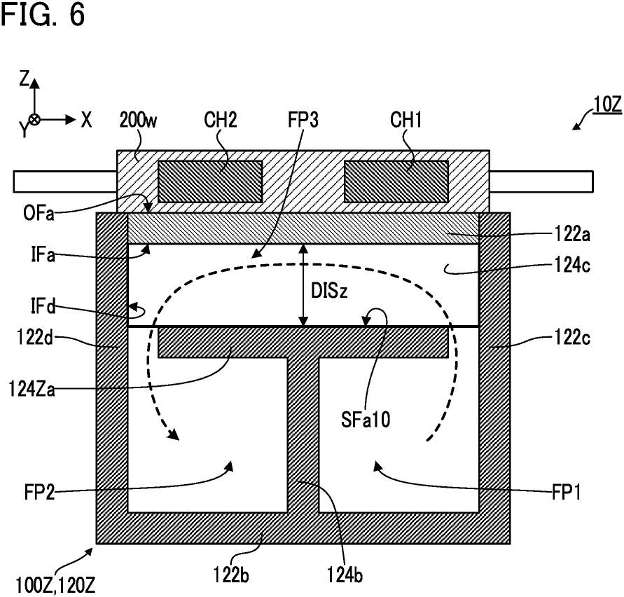

A mode (hereinafter, also referred to as “comparative example”) in which the attachment plates PL and the nozzles N are omitted from the main body portion 120 is explained next as a mode to be compared with the power converter 10 with reference to FIG. 6.

FIG. 6 is an explanatory diagram for explaining an example of a power converter 10Z according to the comparative example. A cross-sectional view of the power converter 10Z corresponding to the cross-sectional view of the power converter 10 illustrated in FIG. 3 is illustrated in FIG. 6. Parts substantially the same as those described with reference to FIG. 1 to FIG. 5 are denoted by like reference signs and detailed descriptions thereof are omitted. The dashed arrows in FIG. 6 indicate flow of refrigerant.

The power converter 10Z is substantially the same as the power converter 10 illustrated in FIG. 1 and the like, except for having a cooler 100Z instead of the cooler 100 illustrated in FIG. 1 and the like. The cooler 100Z is substantially the same as the cooler 100 illustrated in FIG. 1 and the like except for having a main body portion 120Z instead of the main body portion 120 illustrated in FIG. 1 and the like. The main body portion 120Z is substantially the same as the main body portion 120 except that the attachment plates PL and the nozzles N illustrated in FIG. 3 are omitted from the main body portion 120 and that the partition 124a is replaced by a partition 124Za.

For example, the partition 124Za is arranged between the outer walls 122a and 122b. The partition 124Za is substantially parallel to the outer wall 122a, separates the inflow path FP1 from the cooling flow paths FP3, and separates the outflow path FP2 from the cooling flow paths FP3. In the cooler 100Z, a space enabling the inflow path FP1 to communicate with the cooling flow paths FP3 is provided between an edge of the partition 124Za in the +X direction and the inner face IFc of the outer wall 122c. Similarly to the cooler 100, a space enabling the outflow path FP2 to communicate with the cooling flow paths FP3 is provided between an edge of the partition 124Za in the -X direction and the inner face IFd of the outer wall 122d. That is, each of the cooling flow paths FP3 communicates with the inflow path FP1 at one end, and communicates with the outflow path FP2 at the other end also in the cooler 100Z.

In this way, nozzles N are not provided at the communication portion between the inflow path FP1 and the cooling flow paths FP3 in the cooler 100Z. Furthermore, a distance DISz between the inner face IFa of the outer wall 122a and the face SFa10 of the partition 124Za in the cooler 100Z is greater than the distance DIS1 between the inner face IFa (the area AR2) of the outer wall 122a and the face SFa10 of the partition 124a in the cooler 100. Therefore, the flow rate of the refrigerant flowing through each of the cooling flow paths FP3 in the cooler 100Z is lower than that of the refrigerant flowing through each of the cooling flow paths FP3 in the cooler 100. That is, the whole semiconductor module 200 is uniformly cooled by the refrigerant flowing at a low rate in the cooler 100Z. Therefore, the cooling efficiency for the semiconductor chips CH1 and CH2 being heat generating sources is decreased in the cooler 100Z as compared to the cooler 100.

In contrast thereto, the refrigerant is sprayed by the nozzles N extending in the Z direction substantially perpendicularly to the outer wall 122a in the present embodiment, and therefore, the semiconductor chip CH1, being a heat generating source, can be efficiently cooled. Furthermore, in the present embodiment, the flow rate of the refrigerant is increased by narrowing each of the cooling flow paths FP3 of the cooler 100 as compared to each of the cooling flow paths FP3 in the cooler 100Z. As a result, the semiconductor chips CH1 and CH2, being heat generating sources, can be more efficiently cooled in the present embodiment than in the cooler 100Z.

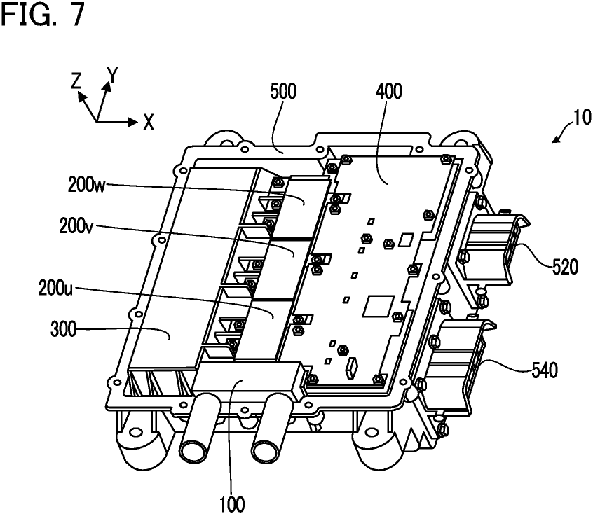

A schematic internal structure of the entire power converter 10 is explained next with reference to FIG. 7.

FIG. 7 is a perspective view illustrating an example of the schematic internal structure of the entire power converter 10.

The power converter 10 has a capacitor 300, a control substrate 400, a casing 500, an input connector 520, an output connector 540, and the like, in addition to the cooler 100 and the semiconductor modules 200 illustrated in FIG. 1 and other drawings. The capacitor 300 smooths a DC voltage applied between the input terminals 202 and 204 of the semiconductor modules 200. A control circuit that controls the semiconductor modules 200, and the like is installed on the control substrate 400. The casing 500 accommodates inner parts of the power converter 10, such as the cooler 100, the semiconductor modules 200, the capacitor 300, and the control substrate 400. The casing 500 is provided with the input connector 520 and the output connector 540. For example, a DC voltage is applied between the input terminals 202 and 204 of the semiconductor modules 200 from a DC power source (not illustrated) via the input connector 520. For example, AC power of three phases including a U phase, a V phase, and a W phase is output from the output terminal 206 of the semiconductor module 200 to an external device (not illustrated; for example, a motor) via the output connector 540.

The configuration of the power converter 10 is not limited to the example illustrated in FIG. 7. For example, since the semiconductor modules 200 are cooled from one side in the present embodiment, the size of the cooler 100 in the Z direction can be decreased. Therefore, a space for arranging other members and the like is provided in the +Z direction of the semiconductor modules 200 in the present embodiment. For example, the control substrate 400 may be arranged in such a manner that a part thereof overlaps with the semiconductor modules 200 in plan view from the +Z direction. In this case, the size of the power converter 10 in the X direction can be decreased, whereas increase in the size of the power converter 10 in the Z direction is suppressed.

As described above, the power converter 10 has the cooler 100 in the present embodiment. The cooler 100 has the main body portion 120 extending in the Y direction. The main body portion 120 has the outer wall 122a including the outer face OFa on which the semiconductor modules 200 are arranged, and the inner face IFa on the opposite side to the outer face OFa. The main body portion 120 further has the inflow path FP1 that extends in the Y direction and in which the refrigerant flows from one end, the outflow path FP2 that extends in the Y direction and that allows the refrigerant to flow out from one end, the cooling flow paths FP3 having the inner face IFa as a part of the wall surface, the partition 124a, and the nozzles N. The partition 124a is arranged to be spaced from the outer wall 122a in the Z direction perpendicular to the outer face OF1, separates the inflow path FP1 from the cooling flow paths FP3, and separates the outflow path FP2 from the cooling flow paths FP3. The nozzles N are provided at the communication portion between each of the cooling flow paths FP3 and the inflow path FP1. The cooling flow paths FP3 are arrayed in the Y direction and extend in the X direction intersecting with the Y direction. The cooling flow paths FP3 are positioned between the inflow path FP1 and the outflow path FP2, and the outer wall 122a in the Z direction. Each of the cooling flow paths FP3 causes the inflow path FP1 and the outflow path FP2 to communicate with each other in the X direction.

As described above, in the present embodiment, the refrigerant in the inflow path FP1 flows in any of the cooling flow paths FP3 via any of the nozzles N. The refrigerant sprayed from the nozzles N impinges, for example, on a portion (for example, the area AR1) of the inner face IFa of the outer wall 122a. For example, the refrigerant is sprayed from the nozzles N to impinge on a portion of the outer wall 122a near a heat generating source (for example, the semiconductor chip CH1) included in the semiconductor module 200 in the present embodiment, so that the heat generating source in the semiconductor module 200 can be efficiently cooled. That is, in the present embodiment, heat in a portion of the semiconductor module 200 near the communication portion between the cooling flow paths FP3 and the inflow path FP1 can be efficiently cooled by way of spraying the refrigerant from the nozzles N. In this way, in the present embodiment, the semiconductor module 200 can be efficiently cooled. That is, the present embodiment can provide cooler 100 that efficiently cools the semiconductor module 200.

Furthermore, in the present embodiment, the nozzles N that cause the refrigerant to flow from the inflow path FP1 into the cooling flow paths FP3 extend along the Z direction. Accordingly, in the present embodiment, heat in the area AR1 including a portion overlapping with the nozzles N on the inner face IFa of the outer wall 122a in plan view from the Z direction can be efficiently transferred to the refrigerant. Therefore, in the present embodiment, a portion near the area AR1 of the outer wall 122a in the semiconductor module 200 can be efficiently cooled.

Furthermore, in the present embodiment, the nozzles N include a portion overlapping with the semiconductor chip CH1, being a heat generating source included in the semiconductor module 200 in plan view from the Z direction. Accordingly, in the present embodiment, the semiconductor chip CH1, being a heat generating source included in the semiconductor module 200, can be efficiently cooled.

### A2: Second Embodiment

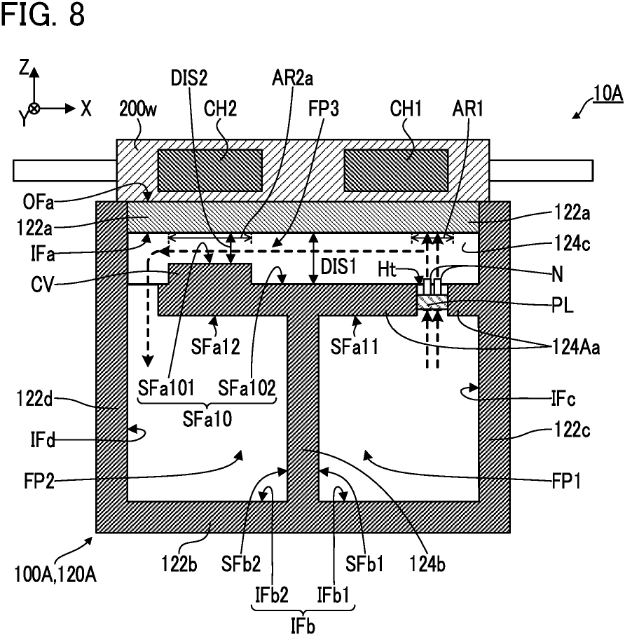

FIG. 8 is an explanatory diagram for explaining an example of a power converter 10A according to a second embodiment. A cross-sectional view of the power converter 10A corresponding to the cross-sectional view of the power converter 10 illustrated in FIG. 3 is illustrated in FIG. 8. Parts substantially the same as those described with reference to FIG. 1 to FIG. 7 are denoted by like reference signs, and detailed descriptions thereof are omitted. The dashed arrows in FIG. 8 indicate the flow of refrigerant.

The power converter 10A is substantially the same as the power converter 10 illustrated in FIG. 1 and the like, except for having a cooler 100A instead of the cooler 100 illustrated in FIG. 1 and the like. The cooler 100A is substantially the same as the cooler 100 illustrated in FIG. 1 and the like, except for having a main body portion 120A instead of the main body portion 120 illustrated in FIG. 1 and the like. The power converter 10A is another example of the “semiconductor device” and the main body portion 120A is another example of the “cooing main body portion.”

The main body portion 120A is substantially the same as the main body portion 120 except for having a partition 124Aa instead of the partition 124a illustrated in FIG. 3. The partition 124Aa is another example of the “partition.”

The partition 124Aa is substantially the same as the partition 124a except for having protruding portions CV. In the present embodiment, a case in which a plurality of protruding portions CV corresponding to the cooling flow paths FP3 on a one-to-one basis, formed on the partition 124Aa, is assumed.

A protruding portion CV is provided, for example, at a location closer to the outflow path FP2 than the inflow path FP1. For example, the protruding portion CV protrudes in a direction approaching the outer wall 122a from at least a part of a portion of the partition 124Aa separating the outflow path FP2 from the cooling flow path FP3. That is, the protruding portion CV protrudes in the +Z direction from a portion of the partition 124Aa between an edge of the partition 124Aa in the -X direction and the partition 124b. In the present embodiment, a case is assumed in which the protruding portion CV is formed to include a portion overlapping with the semiconductor chip CH2 in plan view from the +Z direction. The protruding portion CV is an example of a “first portion.”

A face SFa101 directed to the inner face IFa of the outer wall 122a among the faces of each of the protruding portions CV is a part of the face SFa10 of the partition 124Aa. In the present embodiment, a case in which the faces SFa101 of the protruding portions CV are substantially parallel to the inner face IFa of the outer wall 122a is assumed. It is permissible for the faces SFa101 of the protruding portions CV to not be parallel to the inner face IFa of the outer wall 122a. For example, the face SFa101 of each of the protruding portions CV may be inclined in such a manner that an edge of the face SFa101 in the -X direction is closer to the outer wall 122a.

In FIG. 8, a portion of the face SFa10 directed to the inner face IFa of the outer wall 122a, which is located in the +X direction relative to the faces SFa101 of the protruding portions CV, is also referred to as a “face SFa102.” A portion of the inner face IFa directed to the faces SFa101 of the protruding portions CV is also referred to as an “area AR2a.”

For example, a distance DIS2 between the faces SFa101 of the protruding portions CV and the area AR2a of the outer wall 122a is smaller than the distance DIS1 between the face SFa102 of the partition 124Aa and the inner face IFa of the outer wall 122a. That is, in the present embodiment, the partition 124Aa is formed in such a manner that the distance DIS2 between the faces SFa101 of the protruding portions CV and the inner face IFa is smaller than the distance DIS1 between the face SFa102 of the portion separating the inflow path FP1 from the cooling flow paths FP3 and the inner face IFa. Accordingly, in the present embodiment, the flow of the refrigerant passing between the inner face IFa of the outer wall 122a and the face SFa102 of the partition 124Aa and flowing into the space between the area AR2a of the outer wall 122a and the faces SFa101 of the protruding portions CV is narrowed.

That is, in the present embodiment, a narrowing portion having the face SFa101 of the protruding portion CV and the area AR2a of the outer wall 122a as a part of the wall surface is provided on each of the cooling flow paths FP3. Therefore, each of the cooling flow paths FP3 is an example of the “first cooling flow path” also in the present embodiment. Furthermore, the narrowing portion having the face SFa101 of the protruding portion CV and the area AR2a of the outer wall 122a as a part of the wall surface (the space between the area AR2a of the outer wall 122a and the face SFa101 of the protruding portion CV) is an example of a “second narrowing portion.” Hereinafter, the narrowing portion having the face SFa101 of the protruding portion CV and the area AR2a of the outer wall 122a as a part of the wall surface is also referred to simply as a “narrowing portion of the cooling flow path FP3.”

Focusing on each of the cooling flow paths FP3, the sectional area of the cooling flow path FP3 at a location in the face SFa101 of the protruding portion CV is smaller than the sectional area of the cooling flow path FP3 at a location between the through hole Ht and the protruding portion CV. The sectional area of the cooling flow path FP3 is, for example, the area of the cooling flow path FP3 perceived in sectional view in a case in which the main body portion 120A is cut along a face perpendicular to the X direction. The location, in the face SFa101, of the protruding portion CV is an example of a “location in the second narrowing portion,” and the location between the through hole Ht and the protruding portion CV is an example of a “location between a communication portion between the first cooling flow path and the first flow path, and the second narrowing portion.”

Since the flow of the refrigerant flowing in the space between the area AR2a of the outer wall 122a and the face SFa101 of each of the protruding portions CV is narrowed in the present embodiment, the flow rate of the refrigerant passing through the space between the area AR2a of the outer wall 122a and the face SFa101 of each of the protruding portions CV can be increased. Accordingly, in the present embodiment, the semiconductor chip CH2 overlapping with the protruding portions CV in plan view from the +Z direction can be efficiently cooled.

As described above, the present embodiment can also achieve effects substantially the same as those in the first embodiment described above. Furthermore, in the present embodiment, the cooler 100A has the narrowing portion (the narrowing portion having the face SFa101 of the protruding portion CV and the area AR2a of the outer wall 122a as a part of the wall surface) provided on each of the cooling flow paths FP3. Accordingly, in the present embodiment, the semiconductor chip CH2 overlapping with the narrowing portions of the cooling flow paths FP3 in plan view from the +Z direction among the heat generating sources included in the semiconductor module 200 can be efficiently cooled.

In the present embodiment, the protruding portions CV are provided at locations closer to the outflow path FP2 than the inflow path FP1. That is, in the present embodiment, the narrowing portions of the cooling flow paths FP3 are provided at locations closer to the outflow path FP2 than the inflow path FP1. Therefore, in the present embodiment, the semiconductor chip CH2 positioned at a location far from the inflow path FP1 among the heat generating sources included in the semiconductor modules 200 can be efficiently cooled.

In the present embodiment, the sectional area of each of the cooling flow paths FP3 at a location (for example, a location in the face SFa101) in the narrowing portion of the cooling flow path FP3 is smaller than the sectional area of the cooling flow path FP3 at a location between the communication portion between the cooling flow path FP3 and the inflow path FP1, and the narrowing portion of the cooling flow path FP3. Therefore, in the present embodiment, the flow rate of the refrigerant passing through the narrowing portion of each of the cooling flow paths FP3 can be increased. As a result, in the present embodiment, heat of the semiconductor chip CH2 overlapping with the narrowing portions of the cooling flow paths FP3 in plan view from the +Z direction among the heat generating sources included in the semiconductor modules 200 can be efficiently transferred to the refrigerant.

In the present embodiment, the partition 124Aa is formed in such a manner that the distance DIS2 between each of the protruding portions CV being at least a part of the portion thereof that separates the outflow path FP2 from the associated cooling flow path FP3, and the inner face IFa of the outer wall 122a is smaller than the distance DIS1 between a portion thereof that separates the inflow path FP1 from the associated cooling flow path FP1, and the inner face IFa. Each of the protruding portions CV includes a face being a part of the wall surface of the narrowing portion of the associated cooling flow path FP3. Accordingly, the sectional area of each of the cooling flow paths FP3 at a location in the narrowing portion of the cooling flow path FP3 can be decreased in the present embodiment, while decrease in the size of the cooling flow paths FP3 in the Y direction is suppressed. That is, the flow rate of the refrigerant passing through the narrowing portion of each of the cooling flow paths FP3 can be increased in the present embodiment, while decrease in the contact area between the inner face IFa of the outer wall 122a and the refrigerant is suppressed. As a result, in the present embodiment, the semiconductor chip CH2 overlapping with the narrowing portions of the cooling flow paths FP3 in plan view from the +Z direction among the heat generating sources included in the semiconductor modules 200, can be efficiently cooled.

### A3: Third Embodiment

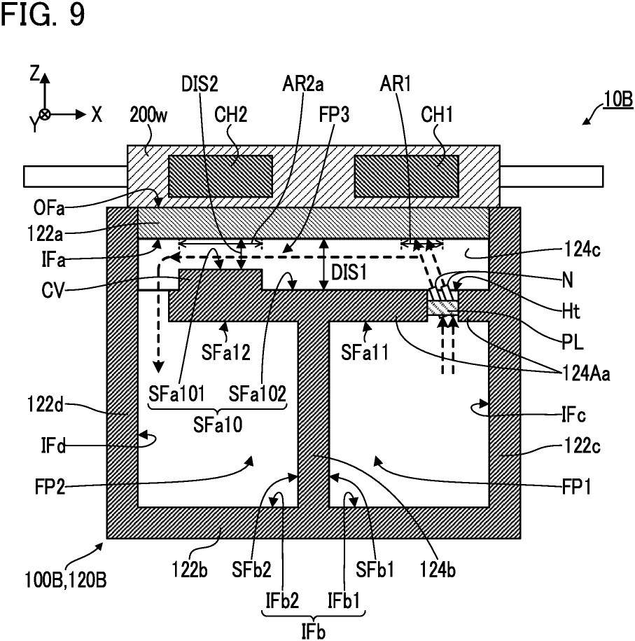

FIG. 9 is an explanatory diagram for explaining an example of a power converter 10B according to a third embodiment. A cross-sectional view of the power converter 10B corresponding to the cross-sectional view of the power converter 10 illustrated in FIG. 3 is illustrated in FIG. 9. Parts substantially the same as those described with reference to FIG. 1 to FIG. 8 are denoted by like reference signs, and detailed descriptions thereof are omitted. The dashed arrows in FIG. 9 indicate the flow of a refrigerant.

The power converter 10B is substantially the same as the power converter 10 illustrated in FIG. 1 and the like, except for having a cooler 100B instead of the cooler 100 illustrated in FIG. 1 and the like. The cooler 100B is substantially the same as the cooler 100 illustrated in FIG. 1 and the like, except for having a main body portion 120B instead of the main body portion 120 illustrated in FIG. 1 and the like. The power converter 10B is another example of the “semiconductor device”, and the main body portion 120B is another example of the “cooling main body portion.”

The main body portion 120B is substantially the same as the main body portion 120A illustrated in FIG. 8 except that the nozzles N are inclined with respect to the Z direction. That is, the cooler 100B is substantially the same as the cooler 100A illustrated in FIG. 8 except that the nozzles N are inclined with respect to the Z direction.

The nozzles N are inclined in such a manner that ends (ends in the +Z direction) being outlets of the refrigerant are positioned in the -X direction relative to ends (ends in the -Z direction) being inlets of the refrigerant. For example, the end of each of the nozzles N in the +Z direction is positioned between a side of the semiconductor chip CH1 in the +X direction out of the two sides along the Y direction and the center of the two sides in plan view from the +Z direction.

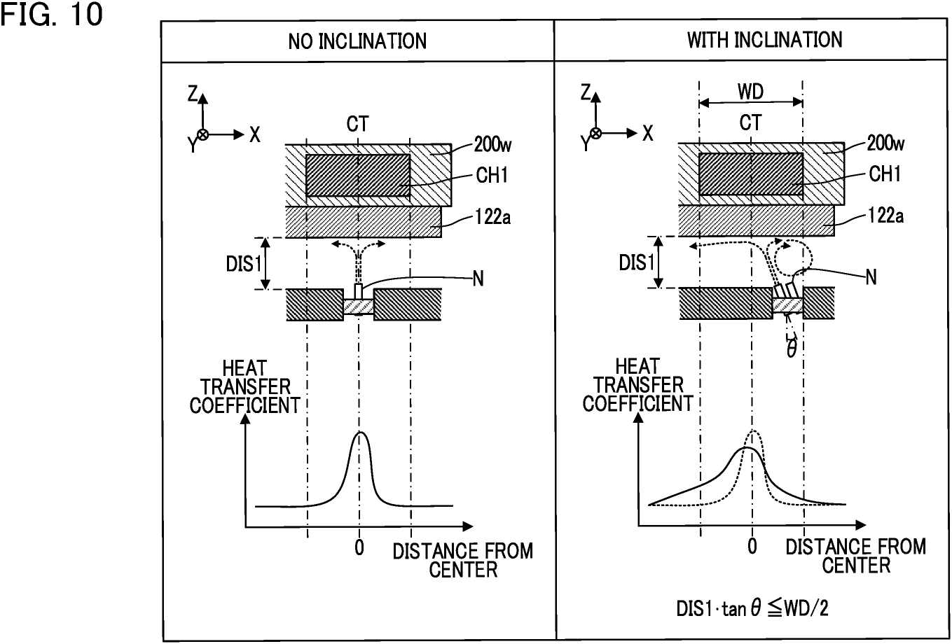

Effects in the case in which the nozzles N are inclined are explained next with reference to FIG. 10.

FIG. 10 is an explanatory diagram for explaining effects of the cooler 100B illustrated in FIG. 9. The vertical axes of graphs in FIG. 10 represent the heat transfer coefficient between the outer wall 122a and the refrigerant, and the horizontal axes of the graphs represent the distance from a center which is the impinging location CT of the refrigerant impinging on the outer wall 122a. The effects in the case in which the nozzles N are inclined are described in FIG. 10 taking a case in which the impinging location CT of the refrigerant matches the center of the semiconductor chip CH1 in the X direction as an example.

The graph of “no inclination” in FIG. 10 shows a relationship between the heat transfer coefficient and the distance from the impinging location CT of the refrigerant in a case in which the nozzles N extend along in the Z direction. The graph of “with inclination” in FIG. 10 shows a relationship between the heat transfer coefficient and the distance from the impinging location CT of the refrigerant in a case in which the nozzles N are inclined with respect to the Z direction. A dotted line in the graph of “with inclination” in FIG. 10 indicates the relationship (the graph of “no inclination” in FIG. 10) between the heat transfer coefficient and the distance from the impinging location CT of the refrigerant in the case in which the nozzles N extend from the Z direction.

In the case in which the nozzles N extend along the Z direction, the maximum value of the heat transfer coefficient is greater than that in the case in which the nozzles N are inclined with respect to the Z direction. However, the heat transfer coefficients at locations far from the impinging location CT of the refrigerant are less than those in the case in which the nozzles N are inclined with respect to the Z direction. For example, when an inclination angle θ of the nozzles N with respect to the Z direction is less, the maximum value of the heat transfer coefficient is greater and the range in which the heat transfer coefficient is improved is less than those when the inclination angle θ is greater.

Therefore, the nozzles N are inclined with respect to the Z direction in the present embodiment to improve the heat transfer coefficient in a wider range than in the case in which the nozzles N extend along the Z direction. For example, when the semiconductor chip CH1 with a distance WD as the size in the X direction is to be efficiently cooled, it is preferable to arrange the nozzles N in such a manner that an expression (1) is met and the center of the semiconductor chip CH1 in the X direction is substantially aligned with the impinging location CT.

$$\text{DIS1} ⋅ \text{tan} \text{θ} \leq \text{WD} / 2$$

When the expression (1) is satisfied, the end in the +Z direction of each of the nozzles N does not need to overlap the semiconductor chip CH1 in plan view from the +Z direction.

As described above, the present embodiment can also achieve effects substantially the same as those in the second embodiment described above. In the present embodiment, one or more nozzles N causing the refrigerant to flow from the inflow path FP1 to each of the cooling flow paths FP3 are inclined with respect to the Z direction. Accordingly, the heat transfer coefficient in a wider range around the impinging location CT between the outer wall 122a and the refrigerant can be enhanced in the present embodiment as compared to the case in which the nozzles N extend along the Z direction.

### A4: Fourth Embodiment

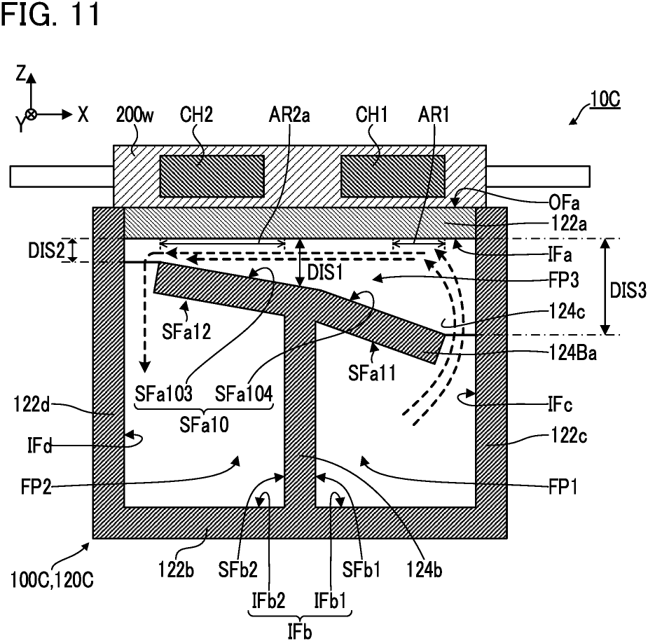

FIG. 11 is an explanatory diagram for explaining an example of a power converter 10C according to a fourth embodiment. A cross-sectional view of the power converter 10C corresponding to the cross-sectional view of the power converter 10 illustrated in FIG. 3 is illustrated in FIG. 11. Parts substantially the same as those described with reference to FIG. 1 to FIG. 10 are denoted by like reference signs and detailed descriptions thereof are omitted. The dashed arrows in FIG. 11 indicate the flow of a refrigerant.

The power converter 10C is substantially the same as the power converter 10 illustrated in FIG. 1 and the like except for having a cooler 100C instead of the cooler 100 illustrated in FIG. 1 and the like. The cooler 100C is substantially the same as the cooler 100 illustrated in FIG. 1 and the like, except for having a main body portion 120C instead of the main body portion 120 illustrated in FIG. 1 and the like. The power converter 10C is another example of the “semiconductor device” and the main body portion 120C is another example of the “cooling main body portion.”

The main body portion 120C is substantially the same as the main body portion 120, except that the attachment plates PL and the nozzles N illustrated in FIG. 3 are omitted from the main body portion 120, and that the partition 124a is replaced by a partition 124Ba. The partition 124Ba is another example of the “partition.”

For example, the partition 124Ba is arranged between the outer walls 122a and 122b, separates the inflow path FP1 from the cooling flow paths FP3, and separates the outflow path FP2 from the cooling flow paths FP3. A portion of the partition 124Ba separating the inflow path FP1 from the cooling flow paths FP3 is a portion in the +X direction relative to the partition 124b, and a portion thereof separating the outflow path FP2 from the cooling flow paths FP3 is a portion in the -X direction relative to the partition 124b.

In the cooler 100C, a space enabling the inflow path FP1 to communicate with the cooling flow paths FP3 is provided between an edge of the partition 124Ba in the +X direction and the inner face IFc of the outer wall 122c. Furthermore, a space enabling the outflow path FP2 to communicate with the cooling flow paths FP3 is provided between an edge of the partition 124Ba in the -X direction and the inner face IFd of the outer wall 122d similarly in the cooler 100. That is, each of the cooling flow paths FP3 communicates with the inflow path FP1 at one end, and communicates with the outflow path FP2 at the other end also in the cooler 100C.

In the present embodiment, the partition 124Ba is formed in such a manner that the face SFa10 directed to the inner face IFa of the outer wall 122a is inclined with respect to the inner face IFa. For example, a portion of the partition 124Ba in the +X direction relative to the partition 124b is inclined in such a manner that the edge in the +X direction is more distant from the outer wall 122a, and a portion thereof in the -X direction relative to the partition 124b is inclined in such a manner that the edge in the -X direction is closer to the outer wall 122a. Therefore, a face SFa104 of a portion in the +X direction relative to the partition 124b in the face SFa10 of the partition 124Ba is inclined in such a manner that an edge in the +X direction is more distant from the inner face IFa of the outer wall 122a. A face SFa103 of a portion in the -X direction relative to the partition 124b in the face SFa10 of the partition 124Ba is inclined in such a manner that an edge in the -X direction is closer to the inner face IFa of the outer wall 122a.

For example, a distance DIS3 between the edge of the face SFa104 of the partition 124Ba in the +X direction and the inner face IFa of the outer wall 122a is equal to or greater than the distance DIS1 between the center of the face SFa10 of the partition 124Ba in the X direction and the inner face IFa. Furthermore, for example, a distance DIS2 between the edge of the face SFa103 of the partition 124Ba in the -X direction and the inner face IFa of the outer wall 122a is less than the distance DIS1. That is, the distance DIS3 between the edge of the partition 124Ba in the +X direction and the inner face IFa of the outer wall 122a is greater than the distance DIS2 between the edge in the -X direction of the partition 124Ba and the inner face IFa of the outer wall 122a. The edge of the partition 124Ba in the +X direction is an edge adjacent to the inflow path FP1 out of the two edges of the partition 124Ba along the Y direction, and is an example of a “first edge.” The edge of the partition 124Ba in the -X direction is an edge adjacent to the outflow path FP2 out of the two edges of the partition 124Ba along the Y direction, and is an example of a “second edge.”

A portion of the inner face IFa of the outer wall 122a directed to the face SFa103 of the partition 124Ba in FIG. 11 is also referred to as “area AR2a.” In the present embodiment, the flow of the refrigerant passing through a space between the inner face IFa of the outer wall 122a and the face SFa104 of the partition 124Ba and flowing into a space between the area AR2a of the outer wall 122a and the face SFa103 of the partition 124Ba is narrowed.

That is, in the present embodiment, a narrowing portion having the face SFa103 of the partition 124Ba and the area AR2a of the outer wall 122a as a part of the wall surface is provided in each of the cooling flow paths FP3. Therefore, also in the present embodiment, each of the cooling flow paths FP3 is also an example of the “first cooling flow path.” The narrowing portion (the space between the area AR2a of the outer wall 122a and the face SFa103 of the partition 124Ba) having the face SFa103 of the partition 124Ba and the area AR2a of the outer wall 122a as a part of the wall surface is another example of the “second narrowing portion.” Hereinafter, the narrowing portion having the face SFa103 of the partition 124Ba and the area AR2a of the outer wall 122a as a part of the wall surface is also referred to simply as “narrowing portion of the cooling flow path FP3.”

Since the flow of the refrigerant flowing in the space between the area AR2a of the outer wall 122a and the face SFa103 of the partition 124Ba is narrowed in the present embodiment, the flow rate of the refrigerant passing between the area AR2a of the outer wall 122a and the face SFa103 of the partition 124Ba can be increased. For example, the flow rate of the refrigerant at a location adjacent to the edge of the face SFa103 of the partition 124Ba in the -X direction is higher than that of the refrigerant at a location far from the edge of the face SFa103 in the -X direction.

For example, the refrigerant at a location adjacent to the edge of the face SFa103 in the -X direction is a refrigerant having performed heat exchange with the semiconductor modules 200. Accordingly, the temperature of the refrigerant at the location adjacent to the edge of the face SFa103 in the -X direction is higher than that of the refrigerant at a location far from the edge of the face SFa103 in the -X direction. Therefore, in the present embodiment, the flow rate of the refrigerant at the location adjacent to the edge of the face SFa103 in the -X direction is increased as compared to that of the refrigerant at the location far from the edge of the face SFa103 in the -X direction to suppress reduction in the cooling efficiency at the location adjacent to the edge of the face SFa103 in the -X direction. As a result, in the present embodiment, the semiconductor chip CH2 overlapping with the face SFa103 of the partition 124Ba in plan view from the +Z direction can be efficiently cooled.

In the present embodiment, the edge of the partition 124Ba in the +X direction is positioned between an edge adjacent to the inflow path FP1 out of two edges of the inner face IFa of the outer wall 122a along the Y direction, and the semiconductor chip CH1 in plan view from the +Z direction. Accordingly, the refrigerant flowing from the inflow path FP1 into the cooling flow paths FP3 moves toward a direction between the +Z direction and the -X direction and impinges on the area AR1 of the inner face IFa of the outer wall 122a. Therefore, in the present embodiment, the semiconductor chip CH1 adjacent to the area AR1 can be efficiently cooled by the refrigerant impinging on the area AR1.

The configuration of the cooler 100C is not limited to the example illustrated in FIG. 11. For example, the inclination angle with respect to the inner face IFa of the outer wall 122a differs between the portion of the partition 124Ba in the +X direction relative to the partition 124b and the portion thereof in the -X direction relative to the partition 124b in FIG. 11. However, the inclination angle may be same in the portion in the +X direction and the portion in the -X direction. The portion of the partition 124Ba in the +X direction relative to the partition 124b may be formed substantially in parallel to the inner face IFa of the outer wall 122a.

Alternatively, the portion of the partition 124Ba in the +X direction relative to the partition 124b may be formed in the same manner as the partition 124Aa illustrated in FIG. 3 or FIG. 8. In this case, the nozzles N may be attached to the portion of the partition 124Ba (a portion formed in the same manner as the partition 124Aa) in the +X direction relative to the partition 124b similarly in FIG. 3 or FIG. 8. Alternatively, it is permissible for the nozzles N to not be attached even in the case in which the portion of the partition 124Ba in the +X direction relative to the partition 124b is formed in the same manner as the partition 124Aa. The portion of the partition 124Ba in the -X direction relative to the partition 124b may be formed in the same manner as the partition 124Aa illustrated in FIG. 3 or FIG. 8.

As described above, the present embodiment can also achieve effects substantially the same as those in the first embodiment described above. For example, in the present embodiment, the distance DIS3 between the edge adjacent to the inflow path FP1 out of the two edges of the partition 124Ba along the Y direction and the inner face IFa of the outer wall 122a is greater than the distance DIS2 between the edge adjacent to the outflow path FP2 out of the two edges and the inner face IFa. Furthermore, the portion of the partition 124Ba separating the outflow path FP2 from the cooling flow paths FP3 includes the face SFa103 being a part of the wall surfaces of the narrowing portions of the cooling flow paths FP3. Accordingly, in the present embodiment, the flow rate of the refrigerant passing between the inner face IFa of the outer wall 122a and the face SFa103 of the partition 124Ba can be increased. As a result, in the present embodiment, the semiconductor chip CH2 overlapping with the face SFa103 of the partition 124Ba in plan view from the +Z direction can be efficiently cooled.

### B: Modifications

The respective embodiments illustrated above can be variously modified. Specific aspects of modifications that can be applied to the respective embodiments described above are illustrated below. Two or more of the aspects freely selected from the following exemplifications may be appropriately combined with each other as long as they do not conflict.

### B1: First Modification

The cooler 100 having the partition 124a on which the nozzles N are installed is illustrated in the first embodiment described above. However, the present invention is not limited to this mode. For example, the cooler 100 does not need to include nozzles N.

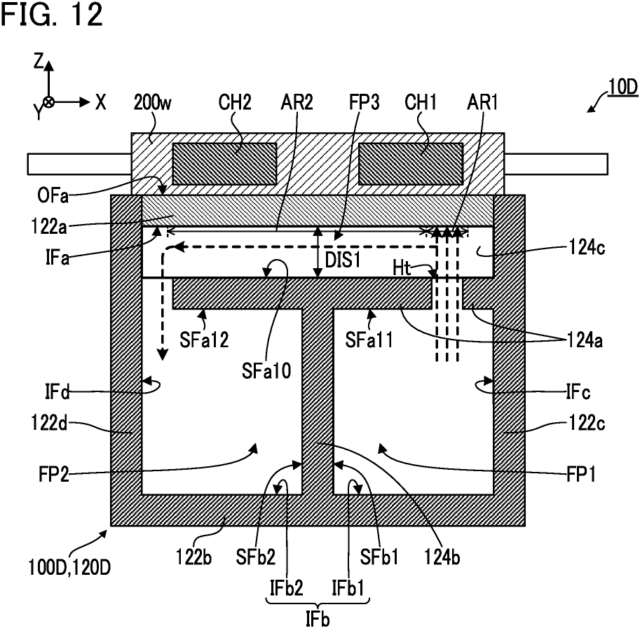

FIG. 12 is an explanatory diagram for explaining an example of a power converter 10D according to a first modification. A cross-sectional view of the power converter 10D corresponding to the cross-sectional view of the power converter 10 illustrated in FIG. 3 is illustrated in FIG. 12. Parts substantially the same as those described with reference to FIG. 1 to FIG. 11 are denoted by like reference signs, and detailed descriptions thereof are omitted. The dashed arrows in FIG. 12 indicate the flow of refrigerant.

The power converter 10D is substantially the same as the power converter 10 illustrated in FIG. 1 and the like, except for having a cooler 100D instead of the cooler 100 illustrated in FIG. 1 and the like. The cooler 100D is substantially the same as the cooler 100 illustrated in FIG. 1 and the like, except for having a main body portion 120D instead of the main body portion 120 illustrated in FIG. 1 and the like. The main body portion 120D is substantially the same as the main body portion 120, except that the attachment plates PL and the nozzles N illustrated in FIG. 3 are omitted from the main body portion 120.

In the present modification, for example, the refrigerant having flowed in the inflow path FP1 passes through the through holes Ht and flows into the cooling flow paths FP3. The refrigerant having flowed in the cooling flow paths FP3 passes between the edge of the partition 124a in the -X direction and the inner face IFd of the outer wall 122d and flows into the outflow path FP2.

In the present modification, the communication portion between each of the cooling flow paths FP3 and the inflow path FP1 is narrowed by the associated through hole Ht. Therefore, the through holes Ht are an example of the “first narrowing portion” in the present modification. For example, the refrigerant in the inflow path FP1 is sprayed substantially perpendicularly to the outer wall 122a due to the through holes Ht corresponding to the cooling flow paths FP3 on a one-to-one basis and flows into the cooling flow paths FP3 in the present modification. Accordingly, the refrigerant impinges on the area AR1 including a portion of the inner face IFa of the outer wall 122a overlapping with the through holes Ht in plan view from the +Z direction. The refrigerant having impinged on the area AR1 on the inner face IFa moves, for example, in the -X direction, substantially parallel to the inner face IFa.

As described above, the present modification can also achieve effects substantially the same as those in the first embodiment described above. Also in the present modification, the protruding portions CV illustrated in FIG. 3 may be formed on the partition 124a. In this case, the present modification can achieve effects substantially the same as those in the second embodiment.

### B2: Second Modification

The cooler 100 including the head portion 140 has been illustrated in the embodiments described above. However, the present invention is not limited to such a mode. For example, the cooler 100 need not include the head portion 140.

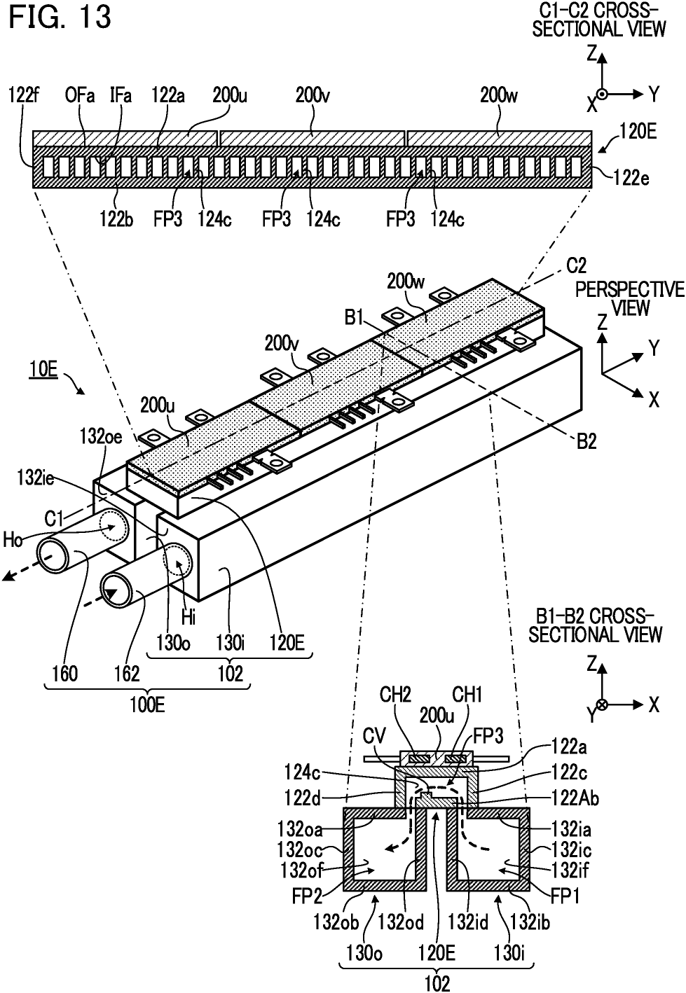

FIG. 13 is an explanatory diagram for explaining an example of a power converter 10E according to a second modification. A perspective view, a B1-B2 cross-sectional view, and a C1-C2 cross-sectional view of the power converter 10E are illustrated in FIG. 13. The B1-B2 cross-sectional view of FIG. 13 is a cross-sectional view of the power converter 10E along a line B1-B2 in the perspective view of FIG. 13. The C1-C2 cross-sectional view of FIG. 13 is a cross-sectional view of a cooling pipe 120E and the semiconductor module 200 along a line C1-C2 in the perspective view of FIG. 13. The dashed arrows in FIG. 13 indicate the flow of a refrigerant. Parts substantially the same as those described with reference to FIG. 1 to FIG. 12 are denoted by like reference signs, and detailed descriptions thereof are omitted.

The power converter 10E has, for example, the three semiconductor modules 200u, 200v, and 200w, and a cooler 100E that cools the semiconductor modules 200u, 200v, and 200w. The cooler 100E has a main body portion 102 extending in the Y direction, the supply pipe 160, and the discharge pipe 162. The power converter 10E is another example of the “semiconductor device,” and the main body portion 102 is another example of the “cooling main body portion.”

The main body portion 102 has the cooling pipe 120E including the cooling flow paths FP3 arrayed in the Y direction and extending in the X direction, a transport pipe 130i including the inflow path FP1 extending in the Y direction, and a transport pipe 130o including the outflow path FP2 extending in the Y direction.

The cooling pipe 120E has, for example, the outer wall 122a and an outer wall 122Ab substantially parallel to the X-Y plane, the outer walls 122c and 122d substantially parallel to the Y-Z plane, and the outer wall 122e and an outer wall 122f substantially parallel to the X-Z plane. A space enabling the inflow path FP1 and the cooling flow paths FP3 to communicate with each other is provided between an edge of the outer wall 122Ab in the +X direction and the outer wall 122c. Similarly, a space enabling the outflow path FP2 and the cooling flow paths FP3 to communicate with each other is provided between an edge of the outer wall 122Ab in the -X direction and the outer wall 122d. That is, the cooling pipe 120E is a hollow cuboid having an opening communicated with the inflow path FP1 and an opening communicating with the outflow path FP2. Furthermore, similarly to the partition 124Aa illustrated in FIG. 8, the protruding portions CV are formed on an edge of the outer walls 122Ab adjacent to the outflow path FP2 out of two edges thereof along the Y direction. Also in the cooling pipe 120E, a narrowing portion with the protruding portion CV is provided in each of the cooling flow paths FP3.

The cooling pipe 120E also has the partitions 124c extending in the X direction and arrayed in the Y direction. Each of the partitions 124c is, for example, a wall substantially parallel to the X-Z plane and is connected to the outer walls 122a, 122Ab, 122c, and 122d. It is permissible for each of the partitions 124c to not be connected to one of the outer walls 122a and 122Ab. Alternatively, it is permissible for each of the partitions 124c to not be connected to the outer walls 122c and 122d. The space in the cooling pipe 120E is divided by the partitions 124c into the cooling flow paths FP3. Also in the cooling pipe 120E, the inner face IFa of the outer wall 122a on which the semiconductor modules 200 are arranged is a part of the wall surfaces of the cooling flow paths FP3.

The transport pipe 130i has, for example, outer walls 132ia and 132ib substantially parallel to the X-Y plane, outer walls 132ic and 132id substantially parallel to the Y-Z plane, and outer walls 132ie and 132if substantially parallel to the X-Z plane. A space enabling the inflow path FP1 to communicate with the cooling flow paths FP3 is provided between an edge of the outer wall 132ia in the -X direction and the outer wall 132id. The supply port Hi penetrating through the outer wall 132ie is formed on the outer wall 132ie. That is, the transport pipe 130i is a hollow cuboid having an opening communicating with the cooling flow paths FP3, and the supply port Hi.

The transport pipe 130o has, for example, outer walls 132oa and 132ob substantially parallel to the X-Y plane, outer walls 132oc and 132od substantially parallel to the Y-Z plane, and outer walls 132oe and 132of substantially parallel to the X-Z plane. A space enabling the outflow path FP2 to communicate with the cooling flow paths FP3 is provided between an edge of the outer wall 132oa in the +X direction and the outer wall 132od. The discharge port Ho penetrating through the outer wall 132oe is formed on the outer wall 132oe. That is, the transport pipe 130o is a hollow cuboid having an opening communicating with the cooling flow paths FP3, and the discharge port Ho.

The cooling pipe 120E is connected to the outer walls 132ia and 132id of the transport pipe 130i, and the outer walls 132oa and 132od of the transport pipe 130o. Accordingly, each of the cooling flow paths FP3 causes the inflow path FP1 and the outflow path FP2 to communicate with each other in the X direction. Also in the present modification, the cooling flow paths FP3 are positioned between the inflow path FP1 and the outflow path FP2, and the outer wall 122a in the Z direction.

The shapes of the cooling pipe 120E, the transport pipe 130i, and the transport pipe 130o are not limited to cuboids extending in the Y direction. For example, the shapes of the transport pipes 130i and 130o in plan view from the -Y direction may be shapes having curved lines. Similarly, the shape of the cooling pipe 120E in plan view from the -Y direction may be a shape having curved lines. The transport pipe 130i, the transport pipe 130o, the supply pipe 160, and the discharge pipe 162 may be made of the same material.

The outer wall 132ib of the transport pipe 130i may be formed integrally with the outer wall 132ob of the transport pipe 130o. In this case, the transport pipes 130i and 130o may have a common partition (for example, the same partition as the partition 124a illustrated in FIG. 3) that separates the inflow path FP1 and the outflow path FP2 from each other, instead of the outer walls 132id and 132od.

As described above, the present modification can also achieve effects substantially the same as those in the embodiments and the modifications described above. For example, the semiconductor chip CH2 overlapping with the protruding portions CV in plan view from the +Z direction can be efficiently cooled also in the present modification. Furthermore, since the head portion 140 is not provided in the present modification, the size of the cooler 100E in the Y direction can be reduced. Also in the present modification, the cooling pipe 120E may have one or more nozzles N illustrated in FIG. 3 or FIG. 8 at the communication portion between each of the cooling flow paths FP3 and the inflow path FP1. In this case, the present modification can achieve effects substantially the same as those in the second and third embodiments described above.

### B3: Third Modification

In the second embodiment described above, the attachment plates PL and the nozzles N may be omitted from the main body portion 120B. Alternatively, the attachment plates PL and one or more nozzles N may be attached between the partition 124Aa and the outer wall 122c in the second and third embodiments described above. In this case, one or more nozzles N may be positioned between the semiconductor chip CH1 and the outer wall 122c in the X direction. As described above, the present modification can also achieve effects substantially the same as those in the embodiments and the modifications described above.

### B4: Fourth Modification

A case in which one or more nozzles N are provided at the communication portion between each of the cooling flow paths FP3 and the inflow path FP1 is illustrated in the first, second, and third embodiments described above. However, the present invention is not limited this mode. For example, in some of the cooling flow paths FP3, it is permissible for no attachment plate PL and no nozzle N to be provided at the communication portion between the cooling flow path FP3 and the inflow path FP1. In this case, the cooling flow paths FP3 in which the refrigerant flows from the communication portion where the attachment plate PL and the nozzles N are installed correspond to the “first cooling flow path.” The present modification can also achieve effects substantially the same as those in the first, second, and third embodiments described above. Holes formed by processing such as punching or burring may be provided instead of the nozzles N. In this case, the partition 124a and the attachment plates PL may be integrally formed. The holes may be formed in a tapered manner narrowing toward the flowing direction, or at a tilt with respect to the plate thickness direction.

### B5: Fifth Modification

A case in which the narrowing portion with the protruding portion CV is installed in each of the cooling flow paths FP3 is illustrated in the second and third embodiments and the second modification described above. However, the present invention is not limited thereto. For example, it is permissible for the narrowing portion with the protruding portion CV to not be installed in some of the cooling flow paths FP3. In this case, the cooling flow paths FP3, in which the narrowing portion with the protruding portion CV is installed, correspond to the “first cooling flow path.” As described above, the present modification can also achieve effects substantially the same as those in the second and third embodiments and the second modification described above.

### B6: Sixth Modification

A case in which each of the cooling flow paths FP3 communicates with the inflow path FP1 at one end and communicates with the outflow path FP2 at the other end is illustrated in the embodiments and the modifications described above. However, the present invention is not limited to this mode. For example, it is permissible for each of the cooling flow paths FP3 to communicate with the inflow path FP1 near an intermediate portion between the inner face IFc of the outer wall 122c and the face SFb1 of the partition 124b, and communicate with the outflow path FP2 near an intermediate portion between the inner face IFd of the outer wall 122d and the face SFb2 of the partition 124b in the X direction. As described above, the present modification can also achieve effects substantially the same as those of the embodiments and the modifications described above.

### DESCRIPTION OF REFERENCE SIGNS

10, 10A, 10B, 10C, 10D, 10E, 10Z... power converter, 100, 100A, 100B, 100C, 100D, 100E, 100Z... cooler, 102, 120, 120A, 120B, 120C, 120Z... main body portion, 122a, 122b, 122Ab, 122c, 122d, 122e, 122ea, 122eb, 132ia, 132oa, 132ib, 132ob, 132ic, 132oc, 132id, 132od, 132ie, 132oe, 142a, 142c, 142e, 142f... outer wall, 124a, 124Aa, 124Ba, 124b, 124c, 144... partition, 120E... cooling pipe, 130i, 130o... transport pipe, 140... head portion, 160... supply pipe, 162... discharge pipe, 200u, 200v, 200w... semiconductor module, 202u, 202v, 202w, 204u, 204v, 204w... input terminal, 206u, 206v, 206w... output terminal, 208u, 208v, 208w... control terminal, 300... capacitor, 400... control substrate, 500... casing, 520... input connector, 540... output connector, CV... protruding portion, FP1... inflow path, FP2... outflow path, FP3... cooling flow path, Hi... supply port, Ho... discharge port, Ht... through-hole, IFa, IFb, IFb1, IFb2, IFc, IFd... inner face, OFa... outer face, SFa10, SFa11, SFa12, SFa101, SFa102, SFa103, SFa104, SFb1, SFb2... face, N... nozzle, PL... attachment plate.

What is claimed is:

1. A cooler comprising a cooling main body portion extending in a first direction, wherein:
the cooling main body portion comprises:
a cooling wall including a first face on which a heat generator is arranged, and a second face opposite to the first face;
a first flow path extending in the first direction and allowing refrigerant to flow in from one end thereof;
a second flow path extending in the first direction and allowing the refrigerant to flow out from one end thereof;
a plurality of cooling flow paths each having a wall surface, a part of which is constituted of the second face;
a partition arranged to be spaced from the cooling wall in a third direction perpendicular to the first face, separating the first flow path from the plurality of cooling flow paths, and separating the second flow path from the plurality of cooling flow paths; and
a first narrowing portion provided at a communication portion between a first cooling flow path among the plurality of cooling flow paths and the first flow path,
the plurality of cooling flow paths are arrayed in the first direction and extend in a second direction intersecting with the first direction, and are positioned between (i) the first and second flow paths and (ii) the cooling wall, in the third direction, and
each of the plurality of cooling flow paths causes the first flow path and the second flow path to communicate with each other in the second direction.

2. The cooler according to claim 1, wherein the first narrowing portion comprises one or more nozzles extending along the third direction and causing the refrigerant to flow from the first flow path to the first cooling flow path.

3. The cooler according to claim 1, wherein the first narrowing portion comprises one or more nozzles inclined with respect to the third direction and causing the refrigerant to flow from the first flow path to the first cooling flow path.

4. The cooler according to claim 1, wherein the first narrowing portion includes a portion overlapping a semiconductor chip being a heat generating source included in the heat generator in plan view from the third direction.

5. The cooler according to claim 1, further comprising a second narrowing portion provided in the first cooling flow path.

6. The cooler according to claim 5, wherein the second narrowing portion is provided at a location closer to the second flow path than the first flow path.

7. The cooler according to claim 6, wherein a sectional area of the first cooling flow path at a location in the second narrowing portion is smaller than a sectional area of the first cooling flow path at a location between (i) a communication portion between the first cooling flow path and the first flow path and (ii) the second narrowing portion.

8. The cooler according to claim 5, wherein:
the partition is formed in such a manner that a distance between a first portion being at least a part of a portion separating the second flow path from the first cooling flow path and the second face is less than a distance between a portion separating the first flow path from the first cooling flow path and the second face, and
the first portion includes a face that is a part of a wall surface of the second narrowing portion.

9. The cooler according to claim 5, wherein:
the partition includes two edges extending along the first direction, including a first edge adjacent to the first flow path and a second edge adjacent to the second flow path,
a distance between the first edge and the second face is greater than a distance between the second edge and the second face, and
a portion of the partition separating the second flow path from the first cooling flow path includes a face that is a part of a wall surface of the second narrowing portion.

10. A cooler comprising a cooling main body portion extending in a first direction, wherein:
the cooling main body portion comprises:
a cooling wall including a first face on which a heat generator is arranged, and a second face opposite to the first face;
a first flow path extending in the first direction and allowing refrigerant to flow in from one end thereof;
a second flow path extending in the first direction and allowing the refrigerant to flow out from one end thereof;
a plurality of cooling flow paths each having a wall surface, a part of which is constituted of the second face;
a partition arranged to be spaced from the cooling wall in a third direction perpendicular to the first face, separating the first flow path from the plurality of cooling flow paths, and separating the second flow path from the plurality of cooling flow paths; and
a second narrowing portion provided in a first cooling flow path among the plurality of cooling flow paths,
the plurality of cooling flow paths are arrayed in the first direction and extend in a second direction intersecting with the first direction, and are positioned between (i) the first and second flow paths and (ii) the cooling wall, in the third direction, and
each of the plurality of cooling flow paths causes the first flow path and the second flow path to communicate with each other in the second direction.

11. The cooler according to claim 10, wherein the second narrowing portion is provided at a location closer to the second flow path than the first flow path.

12. The cooler according to claim 11, wherein a sectional area of the first cooling flow path at a location in the second narrowing portion is smaller than a sectional area of the first cooling flow path at a location between (i) a communication portion between the first cooling flow path and the first flow path and (ii) the second narrowing portion.

13. The cooler according to claim 10, wherein:
the partition is formed in such a manner that a distance between a first portion being at least a part of a portion separating the second flow path from the first cooling flow path and the second face is less than a distance between a portion separating the first flow path from the first cooling flow path and the second face, and
the first portion includes a face that is a part of a wall surface of the second narrowing portion.

14. The cooler according to claim 10, wherein:
the partition includes two edges extending along the first direction, including a first edge adjacent to the first flow path and a second edge adjacent to the second flow path,
a distance between the first edge and the second face is greater than a distance between the second edge and the second face, and
a portion of the partition separating the second flow path from the first cooling flow path includes a face that is a part of a wall surface of the second narrowing portion.

15. The cooler according to claim 14, wherein:
the second face includes two edges extending along the first direction, and
the first edge is positioned between an edge adjacent to the first flow path out of the two edges of the second face and a semiconductor chip being a heat generating source included in the heat generator in plan view from the third direction.

16. A semiconductor device with a cooler comprising a cooling main body portion extending in a first direction, wherein:
the cooling main body portion comprises:
a cooling wall including a first face on which a heat generator is arranged, and a second face opposite to the first face;
a first flow path extending in the first direction and allowing refrigerant to flow in from one end thereof;
a second flow path extending in the first direction and allowing the refrigerant to flow out from one end thereof;
a plurality of cooling flow paths each having a wall surface, a part of which is constituted of the second face;
a partition arranged to be spaced from the cooling wall in a third direction perpendicular to the first face, separating the first flow path from the plurality of cooling flow paths, and separating the second flow path from the plurality of cooling flow paths; and
a first narrowing portion provided at a communication portion between a first cooling flow path among the plurality of cooling flow paths and the first flow path,
the plurality of cooling flow paths are arrayed in the first direction and extend in a second direction intersecting with the first direction, and are positioned between (i) the first and second flow paths and (ii) the cooling wall, in the third direction, and
each of the plurality of cooling flow paths causes the first flow path and the second flow path to communicate with each other in the second direction.

17. A semiconductor device with a cooler comprising a cooling main body portion extending in a first direction, wherein:
the cooling main body portion comprises:
a cooling wall including a first face on which a heat generator is arranged, and a second face opposite to the first face;
a first flow path extending in the first direction and allowing refrigerant to flow in from one end thereof;
a second flow path extending in the first direction and allowing the refrigerant to flow out from one end thereof;
a plurality of cooling flow paths each having a wall surface, a part of which is constituted of the second face;
a partition arranged to be spaced from the cooling wall in a third direction perpendicular to the first face, separating the first flow path from the plurality of cooling flow paths, and separating the second flow path from the plurality of cooling flow paths; and
a second narrowing portion provided in a first cooling flow path among the plurality of cooling flow paths,
the plurality of cooling flow paths are arrayed in the first direction and extend in a second direction intersecting with the first direction, and are positioned between (i) the first and second flow paths and (ii) the cooling wall, in the third direction, and
each of the plurality of cooling flow paths causes the first flow path and the second flow path to communicate with each other in the second direction.
